(19) United States
(12) Patent Application Publication
(10) Pub. No.: US 2009/0201456 A1
(43) Pub. Date: Aug. 13, 2009

(54) LIQUID CRYSTAL DISPLAY DEVICE AND INSPECTION METHOD THEREOF

(75) Inventor: Kenichi WATANABE, Kumamoto (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 12/366,984

(22) Filed: Feb. 6, 2009

(30) Foreign Application Priority Data
Feb. 12, 2008 (JP) 2008-030100

(51) Int. Cl. G02F 1/1345; G02F 1/133; G01R 31/00

(52) U.S. Cl. 349/149; 349/192; 324/770

(57) ABSTRACT

An object of the present invention is to provide a technique capable of adapting to a narrow pitch between bumps of a recent driver LSI without reducing a size of a conductive pattern part. A liquid crystal display device according to the present invention includes a display unit and a plurality of wirings formed on an electrode substrate of the display unit. Thus, the liquid crystal display device according to the present invention further includes a driver LSI, measurement wirings branching from the plurality of wirings positioned between the display unit and the driver LSI, and a conductive pattern part formed above the measurement wiring excluding a branch point through a first insulation layer and formed over the measurement wirings branching from the plurality of wirings.

### BACKGROUND OF THE INVENTION

1. Field of the Invention

The present invention relates to a liquid crystal display device and an inspection method thereof and more particularly, to a liquid crystal display device provided with a driver LSI (Large Scale Integration) to drive a display element and to an inspection method thereof.

2. Description of the Related Art

In view of miniaturization and cost reduction, COG (Chip On Glass) style in which a bump of a driver LSI is directly connected to an electrode terminal of a wiring provided on a glass substrate is employed in a liquid crystal display device in many cases. When a display defect such as a line defect is generated, it is necessary to determine which has a cause, the driver LSI or the wiring in the liquid crystal display device including the COG style.

However, since the wiring is covered with an insulation layer except for a terminal connected to the bump of the driver LSI, it is difficult to find out the cause of the display defect. In order to solve this problem, a method is disclosed in Japanese Patent Application Laid-Open No. 2006-10898. According to a liquid crystal display device in Japanese Patent Application Laid-Open No. 2006-10898, between a driver LSI and a display element, a measurement pattern part having a wide width is provided and a conductive pattern part is provided on the measurement pattern part. Thus, when inspecting a defect, the measuring pattern part and the conductive pattern part are connected by laser irradiation, and a measuring instrument is connected to the conductive pattern part, to confirm an output such as an output signal or an output waveform from the driver LSI to find out the cause of the display defect.

According to the connection style disclosed in Japanese Patent Application Laid-Open No. 2006-10898, the measurement pattern part and the conductive pattern part are arranged in each wiring in order to confirm the defects of the wirings with respect to each wiring. Meanwhile, a pitch of output bumps is required to be narrowed along with recent miniaturization and increase of outputs of the driver LSI. However, in order to measure the output from the driver LSI by surely connecting the parts by the laser irradiation, it is necessary to arrange the measurement pattern part and the conductive pattern part each having a certain size. However, when such measurement pattern part and conductive pattern part are arranged in each wiring, since the pitch between the wirings cannot be narrow, the problem is that a pitch between the bumps cannot be narrow.

### SUMMARY OF THE INVENTION

It is an object of the present invention to provide a technique capable of adapting to a narrow pitch between bumps of a driver LSI without reducing a size of a conductive pattern part.

According to the present invention, a liquid crystal display device includes a display unit, a plurality of wirings, a driver LSI, a plurality of measurement wirings, and a conductive pattern part. The display unit, has two opposed insulation substrates sandwiching a liquid crystal layer and a plurality of display elements. The plurality of wirings is formed on at least one of the insulation substrates to supply a signal to the plurality of display elements. The driver LSI is provided at an edge part exposed outward from the display unit, in the insulation substrate to drive the plurality of display elements when connected to the terminals of the plurality of wirings. The plurality of measurement wirings branches from the plurality of wirings positioned between the display unit and the driver LSI, respectively. The conductive pattern part is formed above the measurement wiring excluding a branch point through a first insulation layer, and formed over the measurement wirings branching from the wirings.

Since the plurality of wirings share the conductive pattern part, the number of the conductive pattern parts can be reduced. Thus, pitches between the wirings can be narrowed without reducing the size of the conductive pattern part, and as a result, the pitch between the bumps of the driver LSI can be narrowed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing a configuration of a liquid crystal display device according to a first embodiment.

FIGS. 2 to 4 are sectional views showing the configurations of the liquid crystal display device according to the first embodiment.

FIG. 5 is an assembly diagram showing the configuration of the liquid crystal display device according to the first embodiment.

FIG. 6 is a plan view showing an inspection method of the liquid crystal display device according to the first embodiment.

FIG. 7 is a sectional view showing the inspection method of the liquid crystal display device according to the first embodiment.

FIG. 8 is a plan view showing the inspection method of the liquid crystal display device according to the first embodiment.

FIGS. 9 to 12 are plan views showing the configurations of the liquid crystal display device according to the first embodiment.

FIG. 13 is a sectional view showing a configuration of a liquid crystal display device according to a second embodiment.

### DESCRIPTION OF THE PREFERRED EMBODIMENTS

### First Embodiment

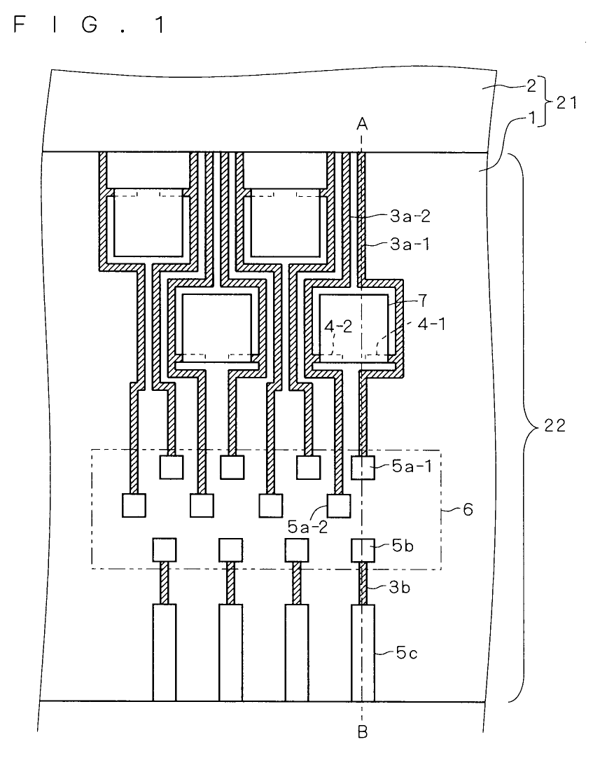

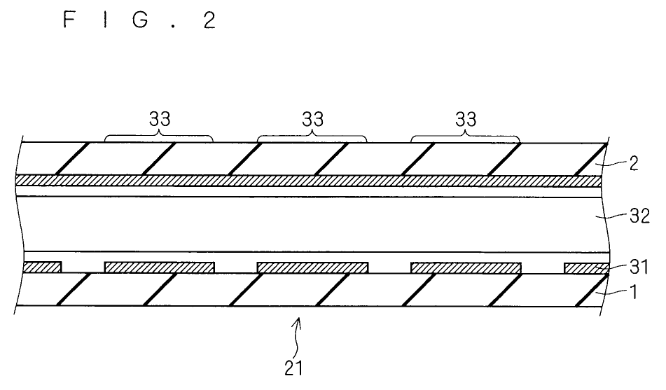

FIG. 1 is a plan view showing a display unit 21 and an electrode terminal part 22 provided in a liquid crystal display device according to the present embodiment. First, a description will be made of a structure of the display unit 21. According to the display unit 21 shown in FIG. 2, a liquid crystal layer 32 is sandwiched by two opposed electrode substrate 1 and opposed substrate 2 serving as insulation substrates (glass substrates, for example), in which a plurality of liquid crystal display elements 33 serving as a plurality of display elements are formed. According to the present embodiment, the electrode substrate 1 protrudes outward (lower side in FIG. 1) from the opposed substrate 2. In addition, a plurality of gate wirings and a plurality of source wirings (not shown) are provided on the electrode substrate 1 of the display unit 21, and a thin film transistor serving as a switching element is provided in the vicinity of an intersection thereof. Thus, pixel electrodes 31 and the like connected to the thin film transistors are arranged in a matrix (they are not shown). The liquid crystal display elements 33 has the pixel electrodes 31.

An opposed electrode formed of a transparent conductive film, a colored filter layer for color display, and a black matrix arranged between the pixels are formed on the opposed substrate 2 of the display unit 21 (they are not shown). The electrode substrate 1 and the opposed substrate 2 of the display unit 21 are superimposed through the liquid crystal layer 32 and a spacer and sealed by a sealing material.

Next, a description will be made of a configuration of the electrode terminal part 22. According to the present embodiment, the electrode terminal part 22 is formed on the electrode substrate 1 protruding outward from the opposed substrate 2 (hereinafter referred to as an edge of the electrode substrate 1 occasionally). In addition, although there are an electrode terminal part on the gate wiring side and an electrode terminal part on the source wiring side as the electrode terminal parts, the electrode terminal part on the gate wiring side will be described in a second embodiment, and the electrode terminal part 22 serving as the electrode terminal part on the source wiring side will be described in the present embodiment. As shown in FIG. 1, the electrode terminal part 22 according to the present embodiment includes wirings 3a-1, 3a-2, and 3b, measurement wirings 4-1 and 4-2, electrode terminals 5a-1, 5a-2, 5b, and 5c, and a conductive pattern part 7. In addition, a right side configuration having reference symbols is the same as the configuration of parts without reference symbols.

A driver LSI serving as a driving IC (Integrated Circuit) for driving the liquid crystal display elements 33 of the display unit 21 is mounted at a position shown by an imaginary line (two-dot chain line) in FIG. 1 in the electrode terminal part 22 according to COG style. Here, a description will be made assuming that a driver LSI 6 that will be illustrated later is mounted on a position of a broken line.

The plurality of wirings 3a-1 and 3a-2 provided in the liquid crystal display device according to the present embodiment are formed on at least one of the electrode substrate 1 and the opposed substrate 2, to supply a signal to the plurality of liquid crystal display elements 33 of the display unit 21. According to the present embodiment, the plurality of wirings 3a-1 and 3a-2 are provided at the edge of the electrode substrate 1, that is, on the electrode substrate 1 protruding outward from the opposed substrate 2. The plurality of wirings 3a-1 and 3a-2 are connected to an output side of the driver LSI 6 to supply the signal from the driver LSI 6 to the thin film transistor of the display unit 21 when they are connected to the source wiring formed on the electrode substrate 1 of the display unit 21. Thus, the wirings 3a-1 and 3a-2 are hereinafter referred to as the source wirings 3a-1 and 3a-2 occasionally. Meanwhile, the wiring 3b is provided between the end of the electrode substrate 1 (lower side in FIG. 1) and the driver LSI 6. The wiring 3b is connected to an input side of the driver LSI 6 to supply a necessary signal and a power from the outside to the driver LSI 6.

According to the present embodiment, the wiring 3a-1 is at an even address (2n), and the wiring 3a-2 is at an odd address (2n+1). In addition, the present invention is not limited thereto, and the wiring 3a-1 may be at the odd address and the wiring 3a-2 may be at the even address. Thus, when it is not necessary to distinguish between the wirings 3a-1 and 3a-2, they are simply referred to as the wiring 3a hereinafter.

According to the liquid crystal display device in the present embodiment, the COG style is employed as described above. Therefore, electrode terminals 5a-1, 5a-2, and 5b to be connected to bumps (not shown in FIG. 1) formed in the driver LSI 6 are connected to the wirings 3a and 3b. When it is not necessary to distinguish between the electrode terminals 5a-1 and 5a-2, they are simply referred to as an electrode terminal 5a hereinafter. An electrode terminal 5c for external input is provided on the input-side wiring 3b on the opposite side of the driver LSI 6. The electrode terminals 5a, 5b, and 5c are formed of ITO (Indium Tin Oxide), for example.

The driver LSI 6 provided in the liquid crystal display device according to the present embodiment is provided at the edge of the electrode substrate 1, and drives the above plurality of liquid crystal display elements 31 of the display unit 21 when connected to the electrode terminals 5a-1 and 5a-2 serving as the terminals of the plurality of wirings 3a-1 and 3a-2. A plurality of measurement wirings 4-1 and 4-2 provided in the liquid crystal display device according to the present embodiment branch from the plurality of output-side wirings 3a-1 and 3a-2 positioned between the display unit 21 and the driver LSI 6 respectively. When it is not necessary to distinguish between the measurement wirings 4-1 and 4-2, they are simply referred to as the measurement wiring 4 hereinafter.

The conductive pattern part 7 provided in the liquid crystal display device according to the present embodiment is formed above the measurement wirings 4-1 and 4-2 excluding a branch point through a first insulation layer, and formed over the measurement wirings 4-1 and 4-2 branching from the plurality of the wirings 3a-1 and 3a-2, respectively. According to the present embodiment, the first insulation layer is a protection film that will be described below. In addition, the branch point herein is a point in which the measurement wiring 4 branches from the wiring 3a.

The conductive pattern part 7 according to the present embodiment is formed over the measurement wiring 4-1 branching from the wiring 3a-1 at the even address, and the measurement wiring 4-2 branching from the wiring 3a-2 at the odd address. Thus, the measurement wiring 4 is provided under the conductive pattern part 7 through the protection film that will be described below. In addition, according to the present embodiment, as shown in FIG. 1, the conductive pattern parts 7 are arranged in zigzags. The conductive pattern part 7 is formed of ITO, for example. The measurement wiring 4 and the conductive pattern part 7 are used to inspect the output such as an output signal or an output waveform of the driver LSI 6, as will be described below.

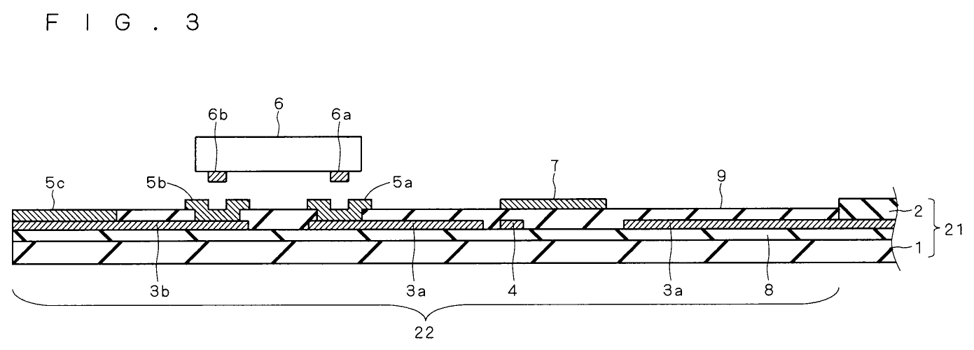

FIG. 3 is a sectional view when the display unit 21 and the electrode terminal part 22 are cut along A-B line shown in FIG. 1. In addition, although the output-side wiring 3a-2, the measurement wiring 4-2, and the electrode terminal 5a-2 are not shown in FIG. 3, their configurations are the same as the output-side wiring 3a-1, the measurement wiring 4-1, and the electrode terminal 5a-1, respectively. Thus, the wirings 3a-1 and 3a-2 are referred to as the wiring 3a collectively, the measurement wirings 4-1 and 4-2 are referred to as the measurement wiring 4 collectively, and the electrode terminals 5a-1 and 5a-2 are referred to as the electrode terminal 5a collectively in the following description. FIG. 3 shows the electrode terminal part 22 on the source wiring side described above. As shown in FIG. 3, a gate insulation film 8 is formed on the edge of the electrode substrate 1, and the output-side wiring 3a, the input-side wiring 3b, and the measurement wiring 4 are formed on the gate insulation film 8.

As shown in the figure, a plurality of bumps 6a and 6b are provided on a back surface of the driver LSI 6. The electrode terminal 5a to be connected to the output bump 6a of the driver LSI 6 is provided at the end of the output-side wiring 3a on the opposite side of the display unit 21. Furthermore, the measurement wiring 4 branching from the output-side wiring 3a is provided at a middle part of the output-side wiring 3a. Thus, a protection film 9 is provided on the measurement wiring 4, and the conductive pattern part 7 formed of ITO is provided on the protection film 9 just above the measurement wiring 4 excluding the branch point. Thus, the conductive pattern part 7 is formed above the measurement wiring 4 excluding the branch point through the protection film 9 serving as the first insulation layer.

Meanwhile, the electrode terminal 5b to be connected to the input bump 6b of the driver LSI 6 is connected to the one end of the input-side wiring 3b on the side of the display unit 21, and the electrode terminal 5c for external input is connected to the other end thereof. The above-described electrode terminals 5a and 5b need to be the same in number as that of the bumps 6a and 6b of the driver LSI 6, and these electrode terminals 5a and 5b are closely arranged to form an electrode terminal block.

Next, a description will be made of a production method for forming the liquid crystal display device according to the present embodiment. First, a production method for forming a part of the display unit 21 on the electrode substrate 1, and a production method for forming the electrode terminal part 22 on the electrode substrate 1 will be described. To begin with, a metal film is formed of Cr, Al, Ta, Ti, or Mo, or an alloy film containing the above metal components as its main component, on a transparent insulation substrate formed of non-alkali glass by sputtering, for example. Then, the film is patterned by photoengraving to form a gate electrode of the display 21, the gate wiring of the display unit 21, and the gate wiring of the electrode terminal part 22 at the same time.

Then, a SiN film is formed by plasma CVD to form the gate insulation film 8. Then, an amorphous Si film serving as a channel layer and N+ type amorphous Si film serving as a contact layer are sequentially formed on the gate electrode, the gate wiring and the gate insulation film 8. After the films have been formed, patterning is performed by photoengraving to form the thin film transistor to drive the liquid crystal display elements 33 of the display unit 21. Furthermore, a metal film is formed of Cr, Al, or Mo or an alloy film containing the above metal component as its main component is formed by sputtering. Then, patterning is performed by photoengraving, to form a drain electrode and a source electrode of the display unit 21, the source wiring of the display unit 21, and the source wirings 3a and 3b of the electrode terminal part 22 at the same time.

Then, in order to prevent a DC component from being applied to the liquid crystal layer 32 of the display unit 21, the protection film 9 is formed a SiN film to form by plasma CVD. Then, the protection film 9 on which the electrode terminal of the gate wiring and the electrode terminals 5a, 5b, and 5c of the source wirings 3a and 3b will be formed is removed. Then, as a final step of the production method, an ITO film is formed by sputtering, and patterned by photoengraving, to form the pixel electrodes 31 of the display unit 21 and the conductive pattern part 7 at the same time. Thus, the conductive pattern part 7 is formed in the same step as the pixel electrodes 31 serving as the conductive film of the liquid crystal display elements 33 of the display unit 21. In addition, the electrode terminal of the gate wiring and the electrode terminals 5a, 5b, and 5c of the source wirings 3a and 3b are formed at the same time as the conductive pattern part 7 and the liquid crystal display elements 33 of the display unit 21.

Since the ITO film is formed, the wiring part formed of Cr or Al is not exposed and an oxide film is prevented from being formed on the electrode terminal, so that a conduction defect of the wiring part can be prevented. Thus, the part of the display unit 21 formed on the electrode substrate 1 and the electrode terminal part 22 of the liquid crystal display device according to the present embodiment are formed through the above steps. In addition, a production method of a part of the display unit 21 formed on the opposed substrate 2 and an assembling step in which the electrode substrate 1 and the opposed substrate 2 are bonded and liquid crystal is injected will not be described here.

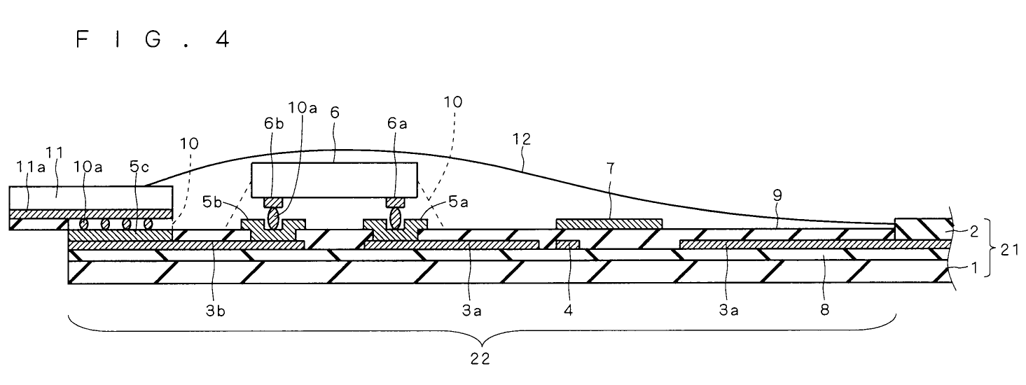

Next, a method for mounting the driver LSI 6 on the electrode terminal part 22 will be described with reference to FIG. 4. An ACF (Anisotropic Conductive Film) 10 is attached on the electrode terminals 5a and 5b formed on the edge of the electrode substrate 1. In FIG. 4, a boundary between the ACF 10 and a coat material 12 that will be described below is shown by a broken line. Then, the plurality of bumps 6a and 6b formed of Au, for example on the back surface of the driver LSI 6 and the electrode terminals 5a and 5b are aligned with high precision and then bonded by thermal compression by use of a hot pressing tool. The condition at this time is such that a heating temperature is set to 170 to 200° C., a process time is for 10 to 20 seconds, and a pressure is set to 30 to 100 Pa.

The ACF 10 is formed by mixing a conductive particle 10a into an insulation epoxy resin. According to the ACF 10, while a productive path is formed by the internal conductive particle 10a only at the part of the thermal compression bonding along its direction, an insulation property thereof is maintained by the internal epoxy resin at the other part in the other direction. Therefore, by the above-described thermal compression bonding, the conductive particle 10a of the ACF 10 sandwiched between the output bump 6a of the driver LSI 6 and the electrode terminal 5a, and between the input bump 6b thereof and the electrode terminal 5b connect the bumps 6a and 6b to the electrode terminals 5a and 5b, respectively. More specifically, the driver LSI 6 is electrically connected to the electrode terminals 5a and 5b by the thermal compression bonding through the ACF 10. Meanwhile, the insulation property is maintained in the horizontal direction with respect to the conduction direction of the ACF 10, by the insulation epoxy resin in the ACF 10.

Then, an FPC (Flexible Printed Circuit) 11 as an external input is connected to the electrode terminal 5c for external input by use of the ACF 10 similarly. Note that the FPC 11 is composed of a polyimide film having a thickness of 30 to 70 μm, a copper foil 11a having a thickness of 8 to 25 μm, and a polyimide solder resist, for example.

As a final step of the mounting method, the insulation coating material 12 is applied to the electrode terminal part 22 containing the wiring 3b between the driver LSI 6 and the FPC 11. As the coating material 12, a silicon resin, an acrylic resin, a fluorine resin, a urethane resin and the like are mainly used, and applied by use of a dispenser. As the coating material 12 is applied to the electrode terminal part 22, the wirings 3a and 3b and the measurement wiring 4 and conductive pattern part 7 are prevented from being corroded.

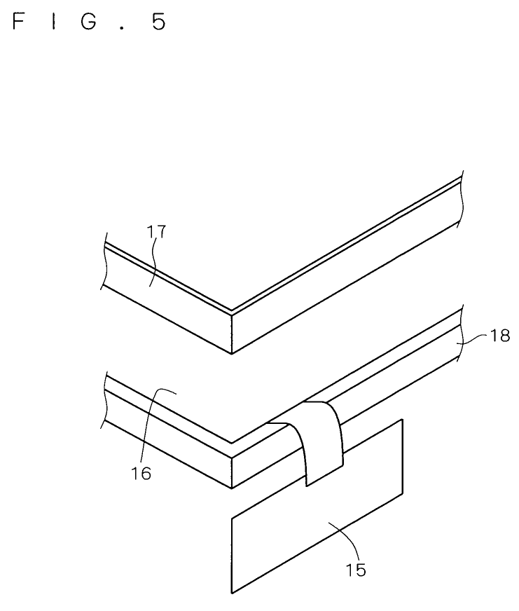

Next, a description will be made of an assembling method of the liquid crystal display device with reference to FIG. 5. The liquid crystal display device according to the present embodiment is assembled by setting a liquid crystal panel 16 on which the driver LSI 6 has been mounted on the electrode substrate 1 through the above steps, on a back light 18 serving as a planar light emitting source, and applying a front frame 17 from the front side of the liquid crystal panel 16. In addition, the FPC 11 connected to the electrode substrate 1 is connected to a circuit substrate 15.

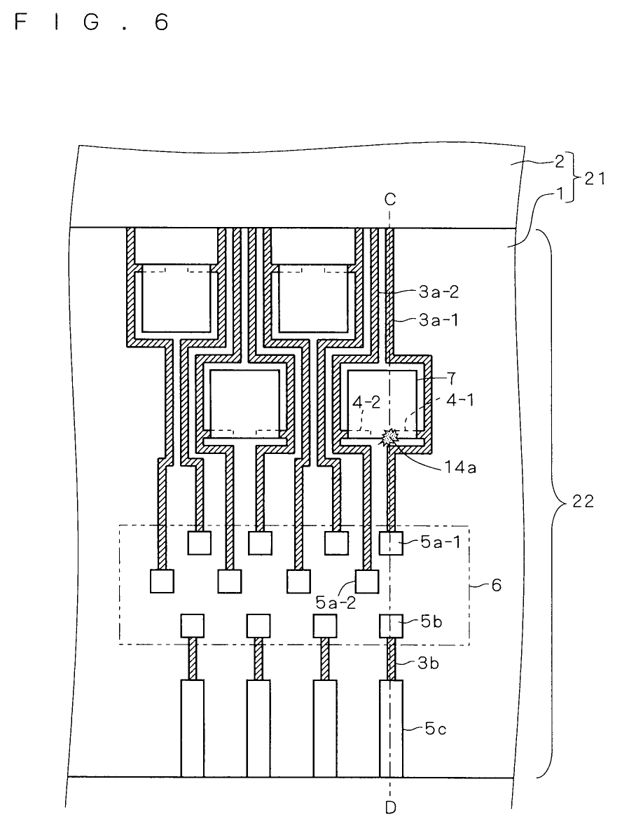

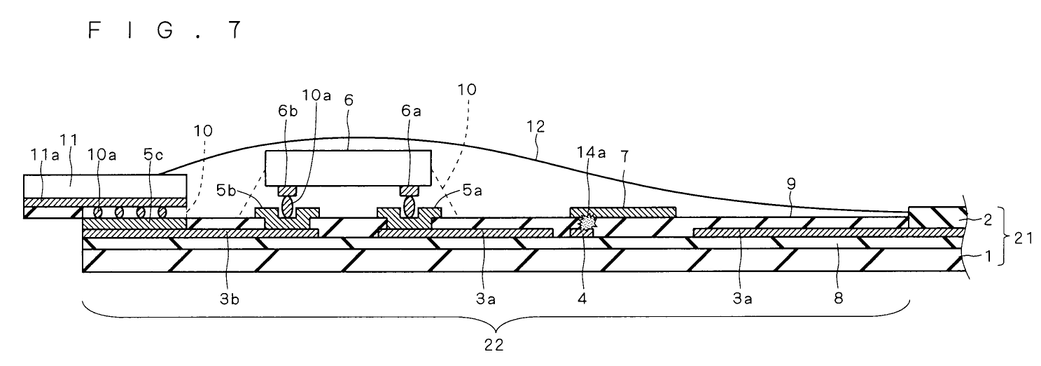

Next, a description will be made of an inspection method when a display defect is generated in the liquid crystal display device according to the present embodiment, with reference to FIGS. 6 and 7. Note that FIG. 7 is a sectional view when the plan view of FIG. 6 is cut along C-D. Here, a description will be made assuming that a defect is generated in the first wiring 3a-1 from the right in FIG. 6. As a first step of the inspection method, the wiring 3a in which the defect is generated in the display unit 21 is specified, and the measurement wiring 4-1 from the specified wiring 3a-1 is connected to the conductive pattern part 7 formed above the measurement wiring 4-1 by laser irradiation. Next, a description will be made of the present step.

According to the present embodiment, a signal is sequentially inputted from a signal generator to each source wiring 3a, in the liquid crystal panel on which the driver LSI 6 and the FPC 11 are mounted. When the signal is inputted, the part in which a predetermined video signal cannot be obtained in the display unit 21, that is, the address of the wiring 3a in which the display defect such as a line defect is generated is specified by the function of the signal generator. Here, since it is assumed that the defect is generated in the wiring 3a-1 in FIG. 6, the wiring 3a-1 is specified by the signal generator.

Then, an overlapped part between a measurement pattern part (the end of the measurement wiring 4-1) of the wiring 3a-1 at the above address and the conductive pattern part 7 is irradiated with laser from the side of the back surface of the electrode substrate 1, that is, from the side of the glass substrate. As shown in FIG. 6, the end of the measurement wiring 4-1 of the first wiring 3a-1 from the right is irradiated with the laser and a laser scar 14a is formed. At the part in which the laser scar 14a is formed, metal at the end of the measurement wiring 4-1 comes up through the protection film 9 and brought in contact with the conductive pattern part 7 due to the heat generated by the laser irradiation. As a result, the end of the measurement wiring 4-1 and the conductive pattern part 7 are short-circuited to be electrically connected. The sectional view in FIG. 7 shows that the measurement wiring 4-1 and the conductive pattern part 7 are short-circuited. In addition, it is desirable that the laser irradiation is performed several times to connect them surely.

After the end of the measurement wiring 4-1 has been connected to the conductive pattern part 7 by the above laser irradiation, the conductive pattern part 7 is touched by a probe or a needle of a measuring instrument such as an oscilloscope or a digital multi-meter. Thus, the conductive pattern part 7 connected to the measurement wiring 4-1 is connected to the measuring instrument to measure the output from the driver LSI 6 and find out a defect cause. The output from the driver LSI 6 herein is the output signal or the output waveform, for example. Thus, even when the conductive pattern part 7 is shared by the wirings 3a-1 and 3a-2, the wiring 3a-1 having the defect is electrically connected to the conductive pattern part 7 individually. Thus, the defect causes of the wirings 3a connected to the same driver LSI 6 can be found with respect to each wiring.

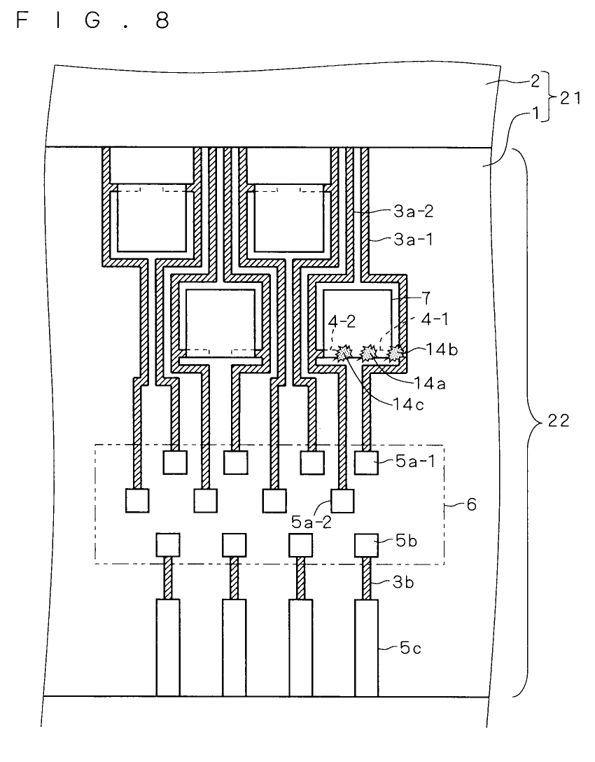

In the above, the description has been made of the case where the defect is generated in one of the wirings 3a-1 and 3a-2 sharing the one conductive pattern part 7. Next, a description will be made of a case where defects are generated in both wirings 3a-1 and 3a-2 sharing the one conductive pattern part 7, and both wirings 3a-1 and 3a-2 are specified by the above signal generator, with reference to FIG. 8. Since a method for finding the defect cause of the wiring 3a-1 is the same as the above, a description thereof will not be given.

After the defect cause of the wiring 3a-1 has been found, the measurement wiring 4-1 from the wiring 3a-1 connected by the above laser irradiation is cut by laser applied between the wiring 3a-1 and the conductive pattern part 7. According to the present embodiment, the measurement wiring 4-1 is cut by irradiating the vicinity of the branch point of the measurement wiring 4-1 with laser. After this laser irradiation, a laser scar 14b is formed in the vicinity of the branch point. The measurement wiring 4-2 from the other wiring 3a-2 specified by the signal generator is connected to the conductive pattern part 7 formed above the measurement wiring 4-2 by laser irradiation.

According to the present embodiment, the measurement wiring 4-2 and the conductive pattern part 7 are connected by irradiating the part between the end of the measurement wiring 4-2 of the wiring 3a-2 and the conductive pattern part 7 with laser. After the laser irradiation, a laser scar 14c is formed. The conductive pattern part 7 connected to the measurement wiring 4-2 by the laser irradiation is touched by the probe or the needle of the measuring instrument similarly to the above, to measure the output from the driver LSI 6 by the measuring instrument to find out the defect cause.

According to the above liquid crystal display device in the present embodiment, the conductive pattern part 7 is formed above the measurement wiring 4 positioned at the edge of the electrode substrate 1 through the protection film 9 serving as the insulation layer. Therefore, when the wiring 3a to be analyzed is connected to the conductive pattern part 7 by the laser irradiation at the time of analyzing the defect, the output such as the output signal or the output waveform of the driver LSI 6 can be inspected easily. In addition, since the wirings 3a-1 and 3a-2 share the one conductive pattern part 7, the number of conductive pattern parts 7 can be reduced. Thus, the pitch between the wirings 3a-1 and 3a-2 can be narrowed without reducing the size of the conductive pattern part 7, so that the pitch between the bumps can be narrowed, which can cope with a future output increase of the driver LSI 6. In addition, since the measurement wiring 4 is formed under the conductive pattern part 7, when the back surface of the electrode substrate 1 is irradiated with the laser, the irradiation part can be easily specified and operation efficiency is improved. In addition, since the conductive pattern part 7 is formed above the measurement wiring 4 excluding the branch point, when the branch point is irradiated with the laser at the time of inspecting the wiring second time, the measurement wiring 4 can be easily cut.

In addition, according to the liquid crystal display device in the present embodiment, the conductive pattern parts 7 are arranged in zigzags. Thus, the pitch between the wirings 3a-1 and 3a-2 can be narrowed without reducing the size of the conductive pattern part 7. As a result, the pitch between the bumps can be narrowed.

In addition, according to the liquid crystal display device in the present embodiment, the conductive pattern part 7 is formed in the same step as the pixel electrodes 31 of the display unit 21. Thus, the number of the production steps can be reduced and a cost can be reduced.

In addition, according to the inspection method of the liquid crystal display device in the present embodiment, although the one conductive pattern part 7 is shared by the wirings 3a-1 and 3a-2, the conductive pattern part 7 is electrically connected to the wiring 3a-1 in which the defect is generated individually. Thus, the defect causes of the wirings 3a connected to the one driver LSI 6 can be found with respect to each wiring. Note that although the wiring connected first by the laser irradiation is the wiring 3a-1 in the above embodiment, the same effect can be achieved even when the wiring is the wiring 3a-2.

In addition, according to the inspection method of the liquid crystal display device in the present embodiment, the wiring 3a-1 connected to the conductive pattern part 7 is cut by the laser irradiation and then, the conductive pattern part 7 is connected to the other wiring 3a-2 by the laser irradiation. Thus, the defect cause in the other wiring 3a-2 can be individually found out independently from the one wiring 3a-1 inspected first.

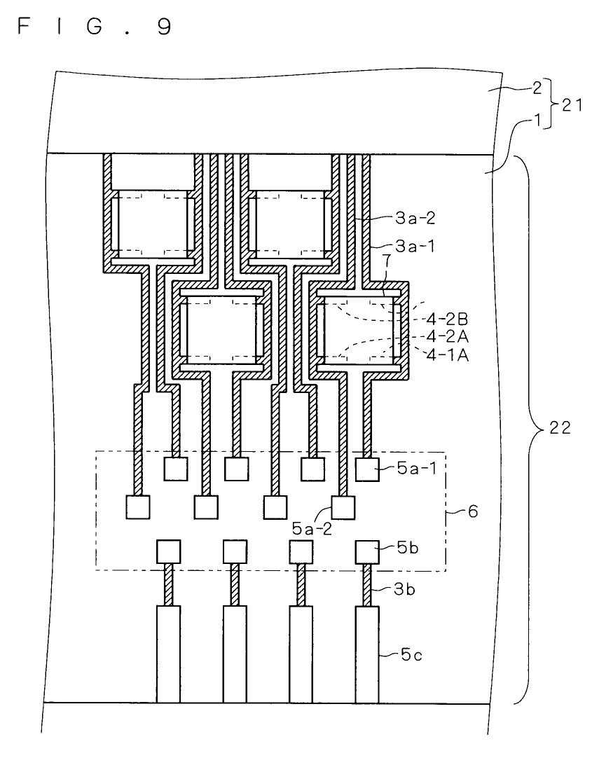

The main configuration of the liquid crystal display device and the main steps of inspection method thereof have been described. Next, a description will be made of a more desirable liquid crystal display device, with reference to FIGS. 9 to 12. According to a liquid crystal display device shown in FIG. 9, a plurality of measurement wirings 4-1A and 4-1B branch from the one wiring 3a-1, and the one conductive pattern part 7 is formed over the plurality of measurement wirings 4-1A and 4-1B branching from the wiring 3a-1. Similarly, a plurality of measurement wirings 4-2A and 4-2B branch from the one wiring 3a-2, and the one conductive pattern part 7 is formed over the plurality of measurement wirings 4-2A and 4-2B branching from the wiring 3a-2.

According to the liquid crystal display device formed as described above, the wiring 3a-1 and the conductive pattern part 7 can be connected at a plurality of points of the plurality of measurement wirings 4-1A and 4-1B. Thus, since the connections are provided at the plurality of points, connection resistance can be lowered, so that the output signal or the output waveform from the driver LSI 6 can be measured to find the defect cause under a more preferable condition.

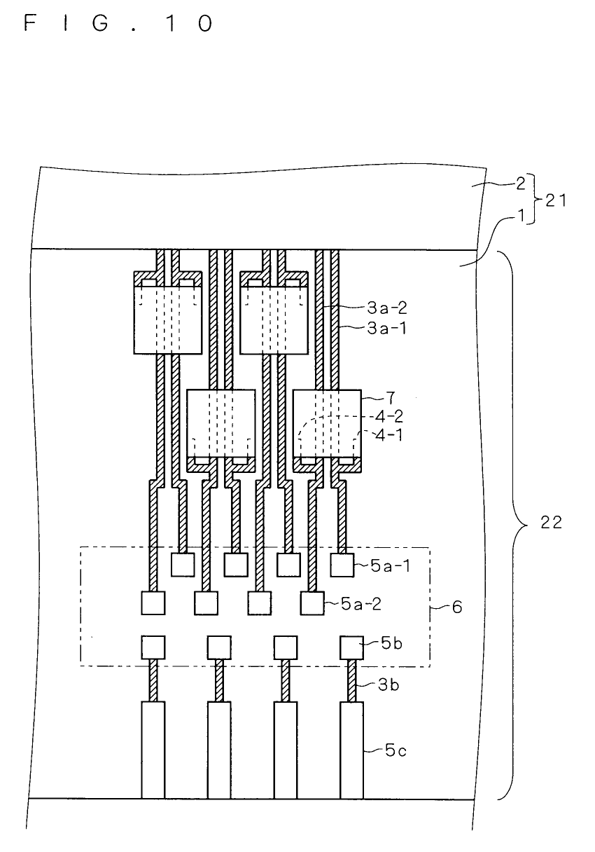

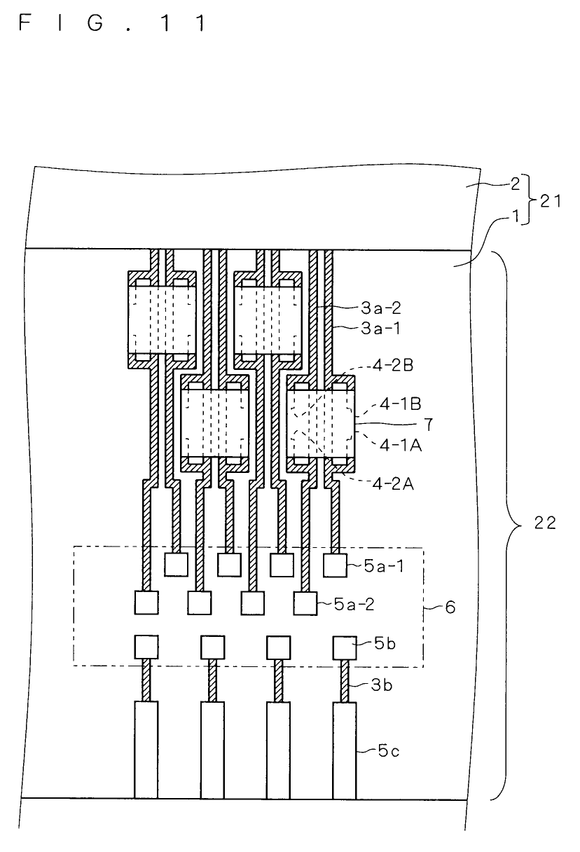

According to the liquid crystal display device shown in FIGS. 10 and 11, each of the plurality of wirings 3a-1 and 3a-2 is arranged under the corresponding conductive pattern part 7 through the protection film 9. Here, the corresponding conductive pattern part 7 designates the conductive pattern part 7 provided above the measurement wiring 4 branching from the wiring 3a. Thus, the pitch between the wirings 3a-1 and 3a-2 can be narrower than that of the liquid crystal display device shown in FIGS. 1 and 9.

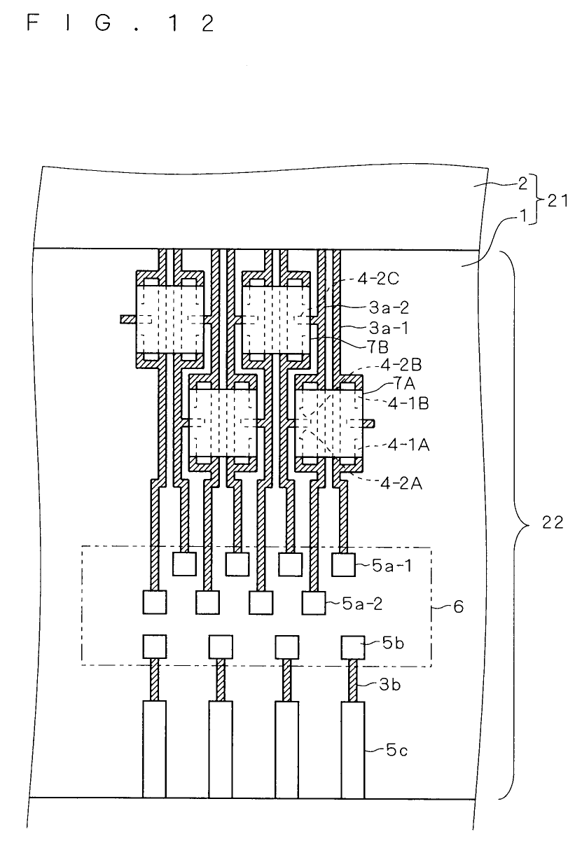

According to a liquid crystal display device shown in FIG. 12, the measurement wirings 4-2A and 4-2B, and a measurement wiring 4-2C branching from the wiring 3a-2 are provided under different conductive pattern parts 7A and 7B, respectively. Thus, the defect cause of the wiring 3a-2 can be found in both conductive pattern parts 7A and 7B. Thus, the number of points capable of measuring the output signal or the output waveform from the driver LSI 6 to the wiring 3a-2 can be increased without increasing the number of the conductive pattern parts 7A and 7B, so that they can be compared easily.

### Second Embodiment

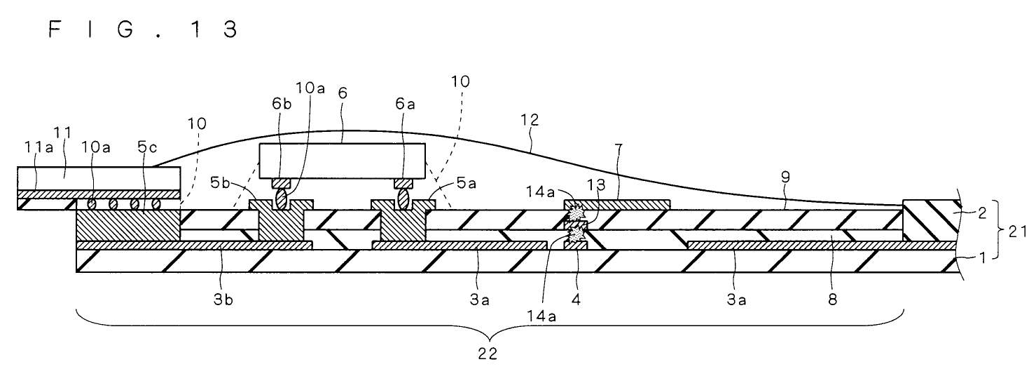

According to the first embodiment, the electrode terminal part 22 formed at the edge of the electrode substrate 1 is the electrode terminal part on the source wiring side. According to the present embodiment, a description will be made of a case where the electrode terminal part 22 formed at the edge of the electrode substrate 1 is the electrode terminal part on the gate wiring side. FIG. 13 is a sectional view when the display unit 21 and the electrode terminal part 22 of the liquid crystal display device in the present embodiment are cut. In addition, the same reference symbols are given to the components of the liquid crystal display device in the present embodiment that correspond to the components of the liquid crystal display device in the first embodiment.

According to the liquid crystal display device in the present embodiment, similar to the liquid crystal display device in the first embodiment, the plurality of wirings 3a are formed on the electrode substrate 1 to supply the signal to the plurality of liquid display elements 33 of the display unit 21. The electrode terminal 5a connected to the output bump 6a of the driver LSI 6 is connected to the end of the output-side wiring 3a on the opposite side of the display unit 21. The electrode terminal 5b connected to the input bump 6b of the driver LSI 6 is connected to the end of the input-side wiring 3b on the side of the display unit 21. The number of the electrode terminals 5a and 5b needs to be the same as that of the plurality of bumps 6a and 6b of the driver LSI 6, and the electrode terminals 5a and 5b are closely arranged to form the electrode terminal block. In addition, the measurement wiring 4 branches from each of the plurality of wirings 3a positioned between the display unit 21 and the driver LSI 6. According to the present embodiment, the measurement wiring 4 branches from the middle part of the wiring 3a.

The electrode terminal part 22 on the gate wiring side according to the present embodiment, unlike the electrode terminal part in the first embodiment, the wirings 3a and 3b, and the measurement wiring 4 are formed under the gate insulation film 8. A metal pad part 13 is provided above the measurement wiring 4 through the gate insulation film 8. The ITO conductive pattern part 7 is provided above the metal pad part 13 through the protection film 9.

Thus, the conductive pattern part 7 according to the present embodiment is formed above the measurement wiring 4 excluding the branch point through the gate insulation film 8 serving as the insulation layer, and formed over the measurement wirings 4 branching from the wirings 3a. Thus, the liquid crystal display device according to the present embodiment is provided with the metal pad part 13 and the protection film 9 serving as a second insulation film between the gate insulation film 8 and the conductive pattern part 7. The metal pad part 13 is provided above the measurement wiring 4, and formed on the gate insulation film 8. The protection film 9 is provided over the metal pad part 13. More specifically, while the measurement wiring 4, the protection film 9, and the conductive pattern part 7 are sequentially laminated according to the first embodiment, the measurement wiring 4, the gate insulation film 8, the metal pad part 13, the protection film 9, and the conductive pattern part 7 are sequentially laminated in the present embodiment.

According to the present embodiment, since a production method for forming the part of the display unit 21 formed on the electrode substrate 1, a production method for forming the electrode terminal part 22 on the electrode substrate 1, a method for mounting the driver LSI 6 on the electrode terminal part 22, and an assembling method of the liquid crystal display device are the same as those in the first embodiment, detailed descriptions thereof will not be given. Next, a description will be made of an inspection method when a display defect is generated in the liquid crystal display device according to the present embodiment. The inspection method according to the present embodiment is almost the same as the inspection method according to the first embodiment basically.

As a first step of the inspection method, a signal is sequentially inputted from a signal generator to each gate wiring 3a on a liquid crystal display panel on which the driver LSI 6 and the FPC 11 are mounted. When the signal is inputted, the part in which a predetermined video signal is not provided in the display unit 21, that is, the address of the wiring 3a in which a display defect such as a line defect is generated is specified by the function of the signal generator. Then, the overlapped part of the end of the measurement wiring 4 of the wiring 3a at the above address with the conductive pattern part 7 is irradiated with laser from the back surface side of the electrode substrate 1, that is, from the glass substrate side. Thus, the laser scar 14a is formed.

At the part in which the laser scar 14a is formed, metal at the end of the measurement wiring 4 comes up through the gate insulation film 8 and brought in contact with the metal pad part 13 due to the heat generated by the laser irradiation. Furthermore, metal of the metal pad part 13 comes up through the protection film 9 and brought in contact with the conductive pattern part 7. As a result, the measurement wiring 4 and the conductive pattern part 7 are short-circuited to be electrically connected. In addition, it is desirable that the laser irradiation is performed several times to connect them for sure.

After the end of the measurement wiring 4 has been connected to the conductive pattern part 7 by the above laser irradiation, the conductive pattern part 7 is touched by the probe or the needle of the measuring instrument such as the oscilloscope or the digital multi-meter. Thus, the conductive pattern part 7 connected to the measurement wiring 4 is connected to the measuring instrument to measure the output from the driver LSI 6 and find out the defect cause.

According to the liquid crystal display device having the above configuration in the present embodiment, since the metal pad part 13 is provided, more metal comes up through the protection film 9 serving as the insulation layer, due to the laser irradiation, so that the measurement wiring 4 and the conductive pattern part 7 are easily and surely connected.

In addition, also in the present embodiment, the measurement wiring 4 and the conductive pattern part 7 as shown in FIGS. 9 to 12 may be provided. With this configuration, the same effect as that described in the first embodiment can be achieved. For example, when the measurement wiring 4 and the conductive pattern part 7 shown in FIG. 9 are provided, similar to the first embodiment, the connection resistance can be lowered by connecting the measurement wirings 4-1A and 4-1B to the conductive pattern part 7. Thus, the output signal or the output waveform from the driver LSI 6 can be measured to find the defect cause under the better condition.

While the invention has been shown and described in detail, the foregoing description is an all aspects illustrative and not restrictive. It is therefore understood that numerous modifications and variations can be devised without departing from the scope of the invention.

What is claimed is:

1. An liquid crystal display device comprising:
a display unit having two opposed insulation substrates sandwiching a liquid crystal layer and having a plurality of display elements;
a plurality of wirings formed on at least one of said insulation substrates to supply a signal to said plurality of display elements;
a driver LSI provided at an edge of said insulation substrate protruding outward from said display unit to drive said plurality of display elements when connected to terminals of said plurality of wirings;
a plurality of measurement wirings branching from said plurality of wirings positioned between said display unit and said driver LSI, respectively; and
a conductive pattern part formed above said measurement wiring excluding a branch point through a first insulation layer, and formed over said measurement wirings branching from said plurality of wirings.

2. The liquid crystal display device according to claim 1, wherein
said plurality of wirings include a wiring at an even address (2n) and a wiring at an odd address (2n+1), and
said conductive pattern part is formed over said measurement wirings branching from the wiring at said even address, and said measurement wirings branching from the wiring at said odd address.

3. The liquid crystal display device according to claim 1, wherein
said conductive pattern parts are arranged in zigzags.

4. The liquid crystal display device according to claim 1, wherein
said plurality of measurement wirings branch from one of said wirings, and
said one conductive pattern part is formed over said plurality of measurement wirings branching from said one wiring.

5. The liquid crystal display device according to claim 1, wherein
each of said plurality of wirings is arranged under said corresponding conductive pattern part through said first insulation layer.

6. The liquid crystal display device according to claim 5, wherein
at least two said measurement wirings branching from said one wiring are provided under said different conductive pattern parts.

7. The liquid crystal display device according to claim 1, further comprising, between said first insulation layer and said conductive pattern part:
a metal pad part provided above said measurement wiring and provided on said first insulation layer; and
a second insulation layer provided over said metal pad part.

8. The liquid crystal display device according to claim 1, wherein
said conductive pattern part is covered with a coating material.

9. The liquid crystal display device according to claim 1, wherein
said conductive pattern part is formed in an identical step as a conductive film of said display element of said display unit.

10. A method for inspecting a liquid crystal display device, wherein
said liquid crystal display device comprises:
a display unit having two opposed insulation substrates sandwiching a liquid crystal layer and having a plurality of display elements;
a plurality of wirings formed on at least one of said insulation substrates to supply a signal to said plurality of display elements;
a driver LSI provided at an edge of said insulation substrate protruding outward from said display unit to drive said plurality of display elements when connected to terminals of said plurality of wirings;
a plurality of measurement wirings branching from said plurality of wirings positioned between said display unit and said driver LSI, respectively; and
a conductive pattern part formed on said measurement wiring excluding a branch point through a first insulation layer, and formed over said measurement wirings branching from said plurality of wirings, and
said inspection method comprising the steps of:
(a) specifying said wiring having a defect in said display unit and connecting said measurement wiring branching from said specified one wiring to said conductive pattern part formed above said measurement wiring, by laser irradiation; and
(b) measuring an output from said driver LSI by connecting said conductive pattern part connected to said measurement wiring by said step (a) to a measuring instrument.

11. The method for inspecting the liquid crystal display device according to claim 10, further comprising the steps of:
(c) cutting said measurement wiring branching from said one wiring and connected at said step (a) by laser irradiation after said step (b);
(d) connecting said measurement wiring branching from said other wiring specified in said step (a) to said conductive pattern part formed above the measurement wiring by laser irradiation; and
(e) measuring an output from said driver LSI by connecting said conductive pattern part connected to said measurement wiring by said step (d) to a measuring instrument.
